(19) United States
(12) Patent Application Publication
(10) Pub. No.: US 2006/0055431 A1
(43) Pub. Date: Mar. 16, 2006

(54) Phase comparator

(75) Inventor: Christian Reichinger, Neutraubling (DE)

Correspondence Address: PHILIPS ELECTRONICS NORTH AMERICA CORPORATION;INTELLECTUAL PROPERTY & STANDARDS, 1109 MCKAY DRIVE, M/S-41SJ, SAN JOSE, CA, 95131, US

(73) Assignee: KONINKLIJKE PHILIPS ELECTRONICS N.V., Eindhoven (NL)

(21) Appl. No.: 10/534,655

(22) PCT Filed: Nov. 3, 2003
(86) PCT No.: PCT/IB03/04880

§ 371 Date: May 10, 2005

(30) Foreign Application Priority Data
Nov. 13, 2002 (DE) 102 53 085.8

(51) Int. Cl. H03D 13/00

(52) U.S. Cl. 327/3

(57) ABSTRACT

A Phase comparator, particularly for a PLL circuit, compares the phase angle of input signals by evaluating the edges of the input signals and generates a regulating signal. To make the regulating signal insensitive to disruptions or interference on the input signals, an additional circuit (4, 5) is provided that evaluates further, different edges of the input signals (SIG, COMP) and generates therefrom additional reset signals for the regulating signals (UP, DOWN).

The invention relates to a phase comparator having the features given in the preamble to claim 1.

In PLL modules, such as the 74HCT9046, there is a built-in phase comparator. This generates a regulating signal when the passages-through-zero of two input signals do not take place synchronously. In the case of devices that operate in a resonant state for example, this function is used to change the operating frequency in such a way that the devices are always operated in resonance even when ambient factors, such as temperature or electrical and/or mechanical loads, cause a change in the resonant frequency. Typical devices that operate in a resonant state are gyroscopes that act as acceleration sensors, in video cameras for example, frequency-analog sensors for pressure, force and temperature in the automobile field, or miniature drives, such as piezomotors, in the semiconductor industry or in printers.

When known phase comparators are used in PLL modules, a circumstance that repeatedly occurs in practice is that if spurious pulses occur the regulation gets out of step, as a result of which the devices fail.

PLL circuits that use a reset pulse for synchronization are described in U.S. Pat. No. 6,066,988, U.S. Pat. No. 6,154,508 and U.S. Pat. No. 6,252,444. Known from U.S. Pat. No. 6,222,420 is a PLL circuit in which a reset stage minimizes the synchronization recovery time.

It is an object of the invention to propose a phase comparator of the kind described in the first paragraph above whose regulating signal (up/down signal) does not get permanently out of step even if there is interference or disruption to the input signal.

In accordance with the invention. the above object is achieved by virtue of the features given in the characterizing clause of claim 1. Because it is not only the rising edges of the input signals that are evaluated to obtain a reset signal but their decaying edges too, the fact of the regulating signal becoming incorrect if there is interference or disruption to the input signal or signals is avoided.

These and other aspects of the invention are apparent from and will be elucidated with reference to the embodiments described hereinafter.

### IN THE DRAWINGS

FIG. 1 shows a prior art phase comparator.

FIG. 2a shows a time plot where the SIG signal occurs before the COMP signal and none of the signals is disrupted.

FIG. 2b shows a time plot where the SIG signal occurs after the COMP signal and none of the signals is disrupted.

FIG. 3a shows a time plot where the SIG signal occurs before the COMP signal and for example a pulse is missing from the SIG signal.

FIG. 3b shows a time plot where the SIG signal occurs before the COMP signal and a pulse is missing from the COMP signal.

FIG. 3c shows a time plot where the SIG signal occurs after the COMP signal and a pulse is missing from the SIG signal.

FIG. 3d shows a time plot where the SIG signal occurs after the COMP signal and a pulse is missing from the COMP signal.

FIG. 4 is a block circuit diagram of an improved phase comparator.

FIG. 5a shows a time plot related to FIG. 4 where the SIG signal occurs after the COMP signal and a pulse is missing from the SIG signal, and

FIG. 5b shows a-time-plot related to FIG. 4 where the SIG signal occurs before the COMP signal and a pulse is missing from the SIG signal.

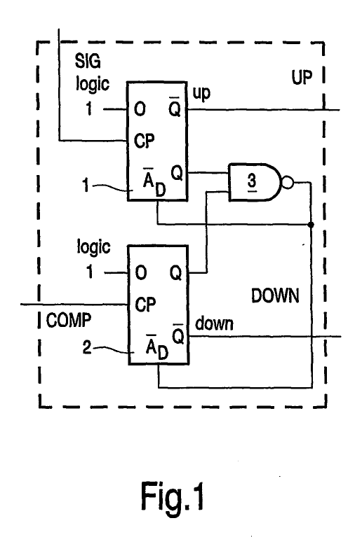

A phase comparator as shown in FIG. 1, of the kind that is used, for example, in a PLL module, e.g. the 74HCT9046, operates with two D flip-flops 1,2 and a NAND gate 3 at the reset inputs of the flip-flops 1, 2. In line with the mutual positions in time of a first input signal SIG and a second input signal COMP, the phase comparator generates an UP signal and a DOWN signal as a regulating signal. The rising edges of the input signals are used to set and reset the UP signal and the DOWN signal, with the first, rising edge generating a sort of set pulse and the second, rising edge of whichever is the other signal generating the associated reset pulse.

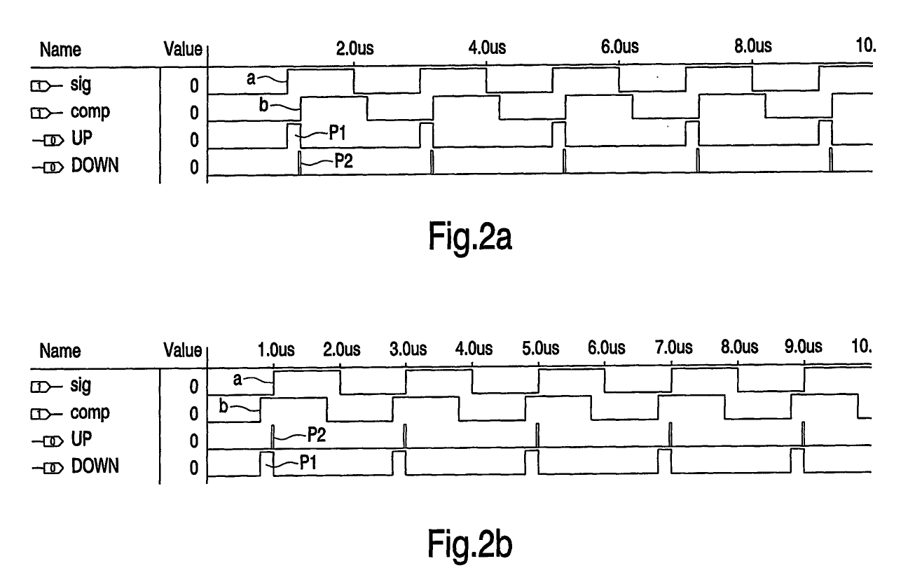

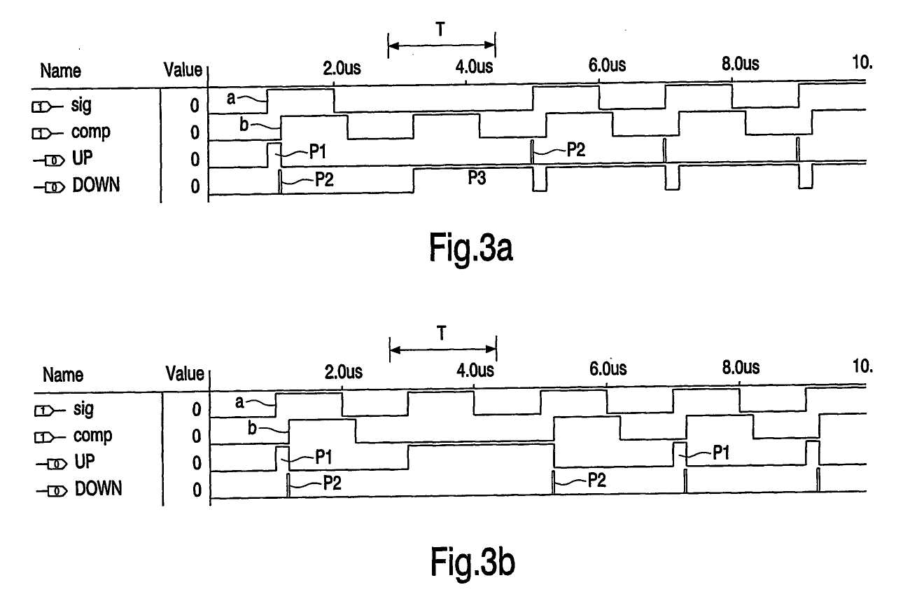

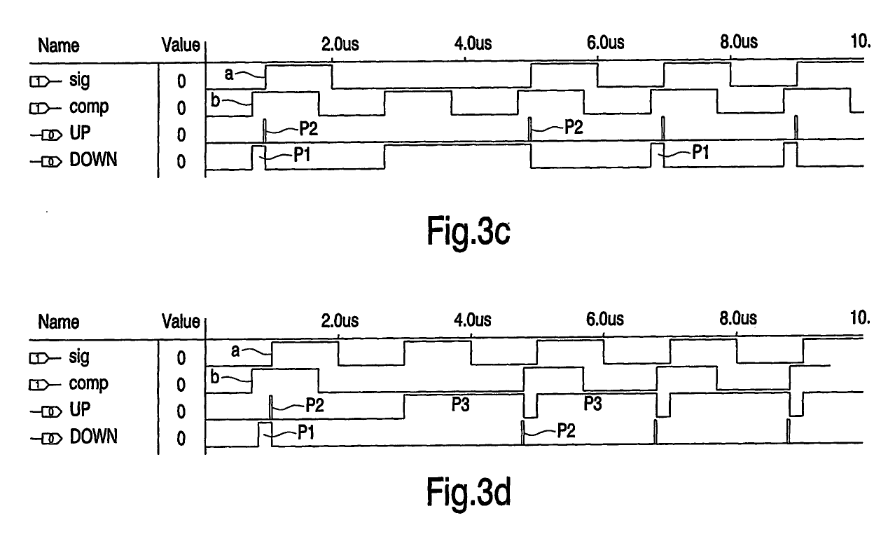

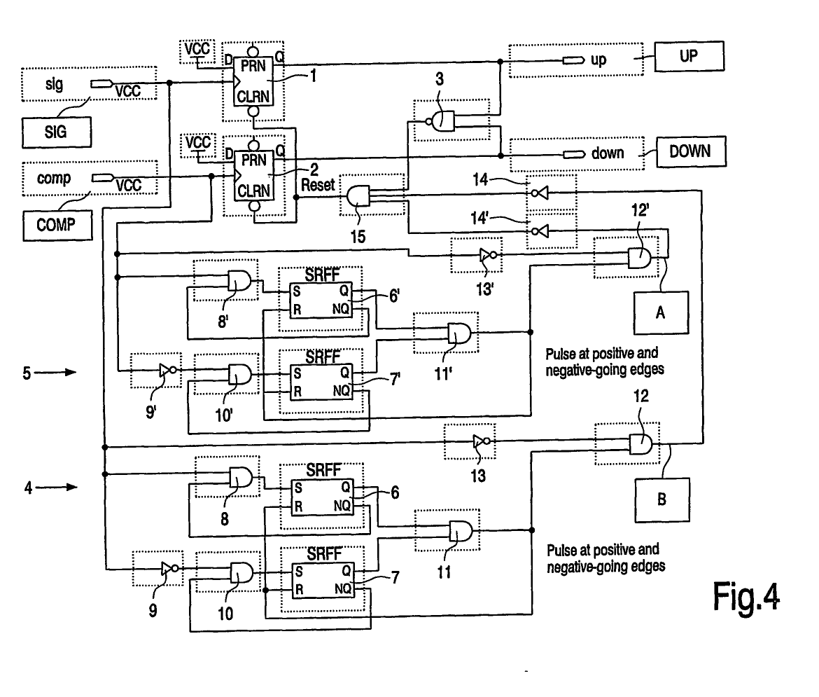

FIGS. 2a, 2b, 3a, 3b, 3c, 3d show signal waveforms for a logic that is inverted in comparison with that shown in FIG. 1, such as would exist, if there were no additional circuits, in the circuit shown in FIG. 4.

FIGS. 2a and 2b show undisrupted operation where the SIG signal and the COMP signal occur regularly. In the example shown in FIG. 2a, the rising edge a of the SIG signal is situated before the rising edge b of the COMP signal each time. The rising edge a sets the UP signal and the rising edge b resets it. A pulse shape P1 is produced. Although the DOWN signal is set by the rising edge b, it is immediately reset again because the SIG signal is at H. This is shown by the pulse shape P2.

In FIG. 2b, the state of affairs is reversed. The SIG signal appears after the COMP signal. The rising edge b of the COMP signal sets the DOWN signal and the following edge a of the SIG signal resets it. This produces the pulse shape P1.

The UP signal is set by the rising edge a of the SIG signal but is immediately reset again because the COMP signal is at H.

If the SIG signal and the COMP signal occur simultaneously, the UP signal and the DOWN signal are of equal length, namely 0 s. The pulse shape P1 changes in line with the distance in time between the rising edges a and b.

In FIGS. 3a to 3d are shown the signals that occur in the event of disruptions where the input signal, namely either the SIG signal or the COMP signal, fails for a brief period, e.g. for an interval T between 3.0 μs and 4.0 μs.

In FIGS. 3a and 3c it is assumed that the SIG signal fails during the interval mentioned, and in FIGS. 3b and 3d it is assumed that the COMP signal fails during the interval T mentioned.

In FIG. 3a, as in FIG. 2a, the SIG signal occurs before the COMP signal. Because the rising edge of the SIG signal is missing during the interval T mentioned, the UP signal is not set during this interval but is only reset by the rising edge of the COMP signal, so that there is a change in polarity and it is not the pulse shape P1 but the pulse shape P2 that occurs subsequently in the UP signal. A corresponding change of phase occurs in the DOWN signal. Because the rising edge of the SIG signal is missing during the interval T mentioned, the DOWN signal is set by the rising edge b of the COMP signal and only reset by the next rising edge a of the SIG signal, which produces the pulse shape P3. This—unsuitable—pulse shape is subsequently maintained. There is thus a change of polarity in the DOWN signal too. A comparison of FIG. 3a with FIG. 2a shows that, after the failure of the SIG signal during the interval T mentioned, the UP signal and the DOWN signal are no longer of the correct shapes.

In FIG. 3a, the single absence of the SIG pulse that, in the temporal sequence shown, originally acted as a SET pulse for the UP signal, changes the action of the COMP signal from a reset pulse both for the UP signal and for the DOWN signal into that of a set pulse for the DOWN signal. In line with this, when the positive-going edge of the SIG signal re-appears, it then acts as a reset pulse both for the UP signal and for the DOWN signal. This produces the altered waveforms for the UP signal and the DOWN signal.

In the example shown in FIG. 3b, the SIG signal occurs before the COMP signal and the COMP signal has failed during the interval T. Although the UP signal and the DOWN signal are disrupted during the interval T, after this they continue again in the correct form (see FIG. 2a), namely the UP signal with pulse shape P1 and the DOWN signal with pulse shape P2.

In FIG. 3c, the SIG signal occurs after the COMP signal and the SIG signal has failed during the interval T. Although the UP signal and the DOWN signal are disrupted during the interval T, after this they continue again in the correct form, namely the UP signal with pulse shape P2 and the DOWN signal with pulse shape P1.

In the example shown in FIG. 3d it is assumed that the SIG signal occurs after the COMP signal and that the COMP signal fails. As in the example shown in FIG. 3a, a permanent change of polarity occurs in this case, where the UP signal changes from pulse shape P2 to pulse shape P3 and the DOWN signal changes from pulse shape P1 to pulse shape P2, even though the SIG signal is still occurring after the COW signal.

Similar changes in polarity also occur as a result of spurious pulses that generate an additional edge on the SIG signal or the COMP signal. The permanent changes of polarity in the UP signal and the DOWN signal (see FIGS. 3a and 3d) mean that the UP signal and/or the DOWN signal regulate in the wrong direction, the final result of which is that the phase regulator (PLL module) that contains the phase comparator will no longer work.

To solve the problem of the unwanted changes in the UP signal and the DOWN signal if there is interference or disruption to the SIG signal or the DOWN signal, or in other words to prevent the sequence of pulse shapes from being permanently disrupted by missing or additional edges in the input signals, decaying edges, and in particular all decaying edges, are used as additional reset pulses.

In the embodiment, it is assumed that it is principally the rising edges of the input signals that are evaluated and that, in line with this, the additional reset pulses are derived from the decaying edges. In a further embodiment it is possible, in a similar but reversed way, for it to be primarily the decaying edges of the input signals that are evaluated and for the additional reset pulses then to be derived from the rising edges.

A block circuit diagram relating to the evaluation of the decaying edges as additional reset pulses is shown in FIG. 4. The SIG signal is applied to a first additional circuit 4 and the COMP signal is applied to a second additional circuit 5. The additional circuits 4 and 5 are easy to integrate into a PLL module and are identical in construction. Each additional circuit 4, 5 (see FIG. 4) operates with two coupled RS flip-flops 6, 7 and gates. In the case of additional circuit 4, the SIG signal is applied to the S input of flip-flop 6 via an AND gate 8. The NO output of flip-flop 6 is connected to AND gate 8. The SIG signal is also applied to the S input of flip-flop 7, via a NOT gate 9 and an AND gate 10. The NO output of flip-flop 7 is connected to AND gate 10 on the input side.

The O outputs of the two flip-flops 6, 7 are connected to an AND gate 11 that is connected on the output side to the R inputs of the two flip-flops 6, 7 and to a farther AND gate 12. The SIG signal is also applied to AND gate 12, via a NOT gate 13. A pulse occurs at the output of AND gate 11 at positive-going and negative-going edges of the SIG signal. At the output B of AND gate 12 there is a signal B. Signal B forms a reset pulse that is generated at each negative-going edge of the SIG signal. However, this reset pulse only goes into action if the COMP signal is missing. When the COMP signal is present, it is simply the reset pulse that is generated by the two rising, positive-going edges of the SIG signal and the COMP signal that acts. The subsequent reset pulse that is generated by the negative-going edge of the SIG signal attempts to again reset a state that has already been reset. Connected downstream of AND gate 12 there is also a NOT gate 14.

The corresponding elements of additional circuit 5, which is of the same construction, are identified by a ′ superscript. There is a pulse at the output of AND gate 11′ at positive-going and negative-going edges of the COMP signal. At the output of AND gate 12′ there is a signal A that represents a reset pulse that is generated at each negative-going edge of the COMP signal but that only goes into action if the SIG signal is missing.

The NOT gates 14, 14′ and the NAND gate 3 are connected to an AND gate 15 that is connected on the output side to the reset inputs CLRN of the flip-flops 1, 2.

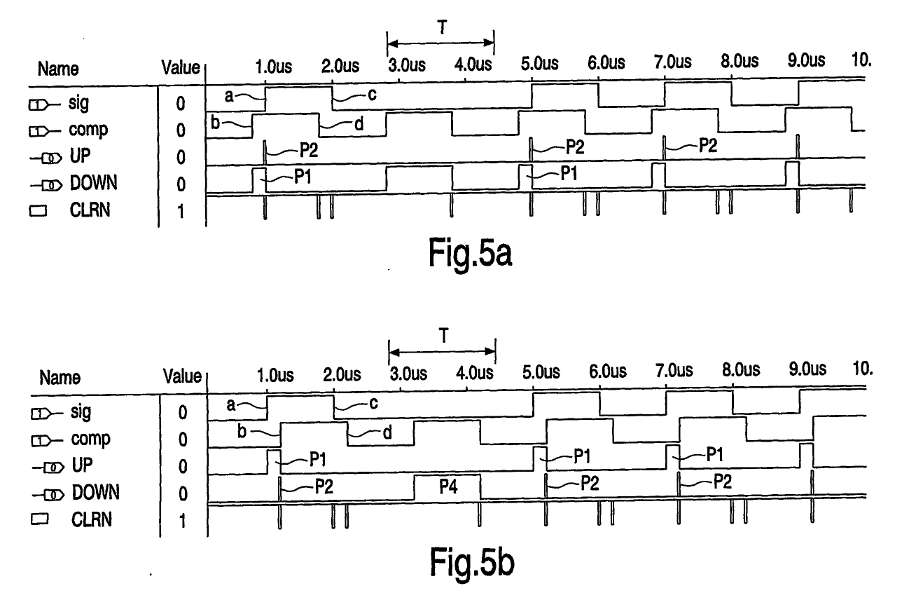

FIGS. 5a and 5b show the operation of the circuit shown in FIG. 4 by way of example. In contrast to FIGS. 2a and 2B and FIGS. 3a to 3d, in FIGS. 5a and 5b the reset signal that is applied to the reset inputs CLRN is shown in addition to the SIG signal, the COMP signal, the UP signal and the DOWN signal.

In FIG. 5a it is assumed, as in FIG. 3c, that the SIG signal occurs after the COMP signal and that the SIG signal fails during the interval T mentioned above. It can be seen here that there are also reset pulses that occur for all the decaying edges c, d of the SIG signal and the COMP signal. Given that the case shown in FIG. 3c is non-critical, nothing particular is achieved by having the reset pulses in the example shown in FIG. 5a .

In the illustrative case shown in FIG. 5b, the SIG signal occurs before the COMP signal and the SIG signal fails, which corresponds to the critical case shown in FIG. 3a. In FIG. 5b, reset pulses occur at the decaying edges of the SIG signal and the COMP signal. These reset pulses, which even occur in the critical interval mentioned, mean that—in contrast to FIG. 3a —after the interval T mentioned the UP signal regains its original pulse shape P1 after the disruption in the interval mentioned. Similarly, after the interval T mentioned—and after a negligible disruption that is caused there by a pulse P4—the DOWN signal too returns to its original pulse shape P2.

In the example shown in FIG. 5b there is, also, no reset pulse at about 5.0 μs. The reset pulse at about 4.0 μs that is generated by the negative-going, decaying edge of the COMP signal sets the logic mentioned back to its original state. The circuit forgets that there was a positive-going edge of the COMP signal.

In the circuit shown in FIG. 4 and in the cases of the faults shown in FIGS. 3b and 3d where there was a failure in the COMP signal, the decaying edge of the SIG signal generates in the additional circuit 4 a reset-pulse that has an identical action.

If a disruption or interference that has a critical effect as shown in FIG. 3d occurs in the circuit shown in FIG. 4, then the result, in this case too, is that after the interval in which the disruption or interference occurs, the pulses P1 and P2 again assume their original shapes. Hence, when there are transient disruptions or interference to the input signals, there is not a permanent change in the UP signal and the DOWN signal after a disruption or interference.

If both input signals fail, then both the UP signal and the DOWN signal remain at logic 0 and thus do not have any effect on the downstream circuit.

The circuit is inexpensive to produce, because the positive-going, rising edges are used for the regular operation of the phase comparator and the negative-going, decaying edges for the additional reset function. The circuit is equally inexpensive to produce if the position is reversed and it is the negative-going edges that are used for the regular operation and the positive-going edges for the additional reset function.

The circuit shown in FIG. 4 can be simplified by gating the SIG signal and the COMP signal together by means of an OR gate and feeding the signal resulting from this operation to the additional circuit 4. The additional circuit 5 can then be dispensed with without losing the additional reset function; the same is true if the logic is reversed.

1. A phase comparator, for a PLL module, that compares the phase angle of a first input signal with a second input signal by evaluating the edges of the input signals and generates reset signals therefrom, characterized in that at least one additional circuit is provided that evaluates further, different edges of the input signal or signals and generates therefrom additional reset signals for the regulating signal or signals.

2. A phase comparator as claimed in claim 1, characterized in that the phase comparator obtains the regulating signals from the rising/decaying edges of the input signals and in that the additional circuit derives the additional reset signals from the decaying/rising edges of the input signals.

3. A phase comparator as claimed in claim 1, characterized in that a dedicated additional circuit is provided for each of the two input signals, with one additional circuit evaluating the edges of the first input signal and the second additional circuit evaluating the edges of the second input signal.

4. A phase comparator as claimed in claim 1, characterized in that one additional circuit evaluates the rising and decaying edges of one input signal and the other additional circuit evaluates the rising and decaying edges of the other input signal.

5. A phase comparator as claimed in claim 1, characterized in that the output signals from the additional circuits are applied to the reset inputs of flip-flops belonging to the phase comparator via a gate, there also being connected to the gate a gate to which the regulating signals are applied.

6. A phase comparator as claimed in claim 1, characterized in that the additional circuits each have two RS flip-flops and gates, which are integrated into the PLL circuit.

7. A phase comparator as claimed in claim 1, characterized in that the two input signals are applied to the additional circuit via an OR gate.
